(19) United States
(12) Patent Application Publication
(10) Pub. No.: US 2024/0192102 A1
(43) Pub. Date: Jun. 13, 2024

(54) APPARATUS FOR MEASURING WAFER BONDING STRENGTH AND METHOD OF OPERATING THE APPARATUS AND METHOD OF MEASURING WAFER BONDING STRENGTH

(71) Applicant: SK hynix Inc., Gyeonggi-do (KR)

(72) Inventors: Jung Hwan PARK, Gyeonggi-do (KR); Ji Hye LEE, Gyeonggi-do (KR)

(21) Appl. No.: 18/475,204

(22) Filed: Sep. 27, 2023

(30) Foreign Application Priority Data
Dec. 9, 2022 (KR) 10-2022-0171346

(51) Int. Cl. G01N 3/16; G01N 3/04

(52) U.S. Cl. CPC G01N 3/16; G01N 3/04; G01N 2203/0019; G01N 2203/0676

(57) ABSTRACT

An apparatus for measuring wafer bonding strength may include a wafer fixer and measuring unit. The wafer fixer may be configured to fix bonded wafers. The measuring unit may be configured to measure bonding strength of the bonded wafers. The measuring unit may include a blade, a driver and a sensor. The blade may apply a force to an interface between the bonded wafers to separate the bonded wafers from each other. The driver may provide the blade with a driving force. The sensor may measure the force applied to the blade.

### CROSS-REFERENCES TO RELATED APPLICATION

The present application claims priority under 35 U.S.C. § 119(a) to Korean application number 10-2022-0171346, filed on Dec. 9, 2022, in the Korean Intellectual Property Office, which is incorporated herein by reference in its entirety.

### BACKGROUND

### 1. Technical Field

The technical field of the present invention generally relates to an apparatus for measuring wafer bonding strength, a method of operating the apparatus and a method of measuring wafer bonding strength.

### 2. Related Art

As a semiconductor device have been more highly integrated, a bond wafer including a plurality of wafers bonded to each other by a wafer bonding process has been used.

However, when bonding strength between bonding interfaces of the bond wafer, i.e., the wafer bonding strength may not be sufficiently strong, an error may be generated at the bond wafer in various processes after the wafer bonding process. For example, a part or whole of the bond wafer may be removed in a transfer process. Further, a separation or a delamination of the bond wafer may be generated in a dicing process. Furthermore, because the low wafer bonding strength may cause a low yield, it may be required to measure and manage the wafer bonding strength.

One method of measuring the wafer bonding strength may include a crack opening method. In the crack opening method, a crack length, which may be generated by opening or separating an edge portion of the bond wafer using a blade, may be measured. Surface energy may be inferred from the crack length to determine the wafer bonding strength.

### SUMMARY

According to disclosed embodiments herein, there may be provided an apparatus for measuring wafer bonding strength. The apparatus may include a wafer fixer and measuring unit. The wafer fixer may be configured to fix bonded wafers in position. The measuring unit may be configured to measure bonding strength of the bonded wafers. The measuring unit may include a blade, a driver and a sensor. The blade may apply a force to an interface between the bonded wafers to separate the bonded wafers from each other. The driver may provide the blade with a driving force. The sensor may measure the force applied to the blade.

According to other embodiments, there may be provided a method of measuring wafer bonding strength. In the method of measuring the wafer bonding strength, a blade may apply a force to an interface between bonded wafers. The force applied to the blade may then be measured to determine bonding strength of the bonded wafers.

According to still other embodiments, there may be provided a method of operating an apparatus for measuring wafer bonding strength. The method may include fixing bonded wafers and measuring a bonding strength of the bonded wafers. Measuring the bonding strength of the bonded wafers may include applying a force to a blade making contact with an interface between the bonded wafers by driving a driver to provide the blade with a driving force, and measuring the force applied to the blade to determine the bonding strength of the bonded wafers.

The apparatus may include a wafer fixer and measuring unit. The wafer stage may be configured to fix bonded wafers. The measuring unit may be configured to measure bonding strength of the bonded wafers. The measuring unit may include a blade, a driver and a sensor. The blade may apply a force to an interface between the bonded wafers to separate the bonded wafers from each other. The driver may provide the blade with a driving force. The sensor may measure the force applied to the blade.

According to further embodiments, a crack opening force, which may directly relate to the wafer bonding strength, i.e., a maximum blade force may be directly measured to determine the bonding strength of the bonded wafers. Thus, an accuracy of the wafer bonding strength may be improved by the directly measurement. Further, the example method may not be relatively affected by peripheral environments, measurement methods, etc., compared to a crack opening method so that factors of the example method, which may affect the measurement of the wafer bonding strength, may be very small in number. Therefore, the wafer bonding strength may have improved accuracy and precision.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a plan view illustrating an apparatus for measuring wafer bonding strength in accordance with one or more embodiments;

FIG. 2 is a cross-sectional view taken along a line II-II′ in FIG. 1;

FIG. 3 is a plan view illustrating a wafer fixer in an apparatus for measuring wafer bonding strength in accordance with other embodiments;

FIG. 4 is a flow chart illustrating a method of operating a measurement apparatus of wafer bonding strength in accordance with still other embodiments;

FIG. 5 is a graph showing blade forces in accordance with times in an apparatus for measuring wafer bonding strength in accordance with further embodiments;

FIG. 6 is a graph showing a relation between a waiting time after wafer bonding and a maximum blade force measured using an apparatus of the above-noted embodiments; and

FIG. 7 is a graph showing a maximum blade force measured using an apparatus of the above-noted embodiments and wafer bonding strength by a crack opening method.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the scope of the present invention.

The present invention is described herein with reference to cross-section and/or plan illustrations of the disclosed embodiments of the present invention. However, the disclosed embodiments of the present invention should not be construed as limiting the inventive concept. Although a few embodiments of the present invention will be shown and described, it will be recognized by those of ordinary skill in the art that changes are readily apparent based on these disclosed embodiments without departing from the principles of the present invention.

The present invention realized that, in the crack opening method noted above, the crack length may be measured at a point where a deboning wave may spread after the edge portion of the bond wafer may be separated. Thus, factors affecting the wafer bonding strength may be so numerous so that there may exist a limit for increasing an accuracy and a precision. That is, the crack opening method may be affected by peripheral environments such as a temperature, a humidity, etc. Further, the crack opening method may be affected by specification of measurement apparatuses such as a light source, a camera, a stage, etc. Therefore, an error or a fluctuation may be generated in the wafer bonding strength measured by the crack opening method.

Further, because the crack opening method may use the indirect method of inferring the surface energy from the crack length, there may exist a limit for improving the accuracy of the wafer bonding strength. Furthermore, it may also be difficult to compare the wafer bonding strength measured by the crack opening method with a wafer bonding strength measured by other methods. It is in this context that the present invention is provided.

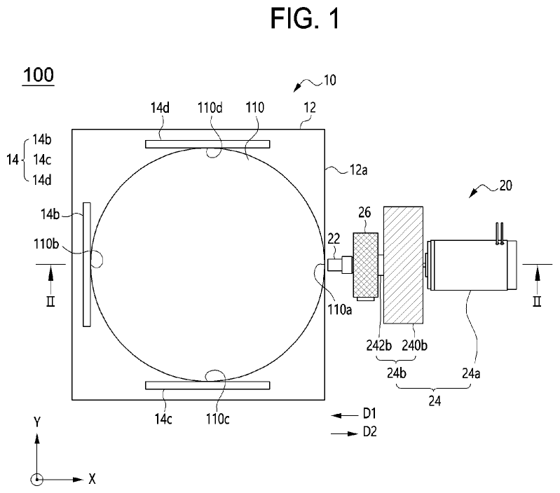

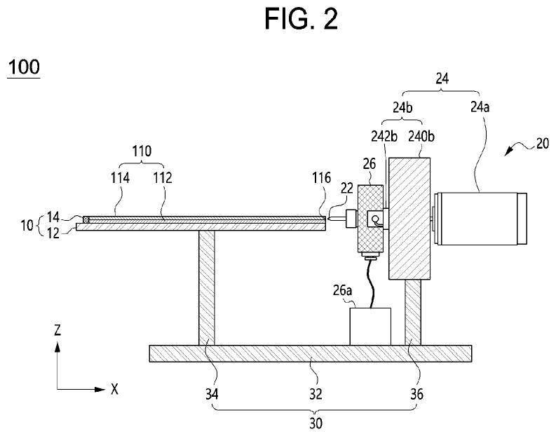

FIG. 1 is a plan view illustrating an apparatus for measuring wafer bonding strength in accordance with various embodiments, and FIG. 2 is a cross-sectional view taken along a line II-II′ in FIG. 1. A support frame 30, and an analyzer 26a, etc., are depicted in FIG. 2.

Referring to FIGS. 1 and 2, an apparatus 100 for measuring a wafer bonding strength may include a wafer fixer 10 and a measuring unit 20. The wafer fixer 10 may be configured to fix thereon a bonded wafer pair 110. The measuring unit 20 may be configured to measure a bonding strength of the bonded wafer pair 110, i.e., the wafer bonding strength. The measuring unit 20 may include a blade 22, a driver 24 and a sensor 26. The apparatus 100 may further include a support frame 30 configured to fix and support the wafer fixer 10 and the measuring unit 20.

In various embodiments, the support frame 30 may include a bottom portion 32, a first fixing portion 34 and a second fixing portion 36. The bottom portion 32 may be fixed to a bottom surface of a floor. The first fixing portion 34 may be upwardly extended from a first position of the bottom portion 32 to fix in position and support the wafer fixer 10. The second fixing portion 36 may be upwardly extended from a second position of the bottom portion 32 to fix in position and support the measuring unit 20. The wafer fixer 10 and the measuring unit 20 may be spaced apart from each other by the first fixing portion 34 and the second fixing portion 36.

In other embodiments, the measuring unit 20 may provide the bonded wafer pair 110 with a force to measure the wafer bonding strength. Thus, when relative positions between the bonded wafer pair 110 or the wafer fixer 10 and the measuring unit 20 are changed in measuring the wafer bonding strength, the wafer bonding strength is not accurately measured. The support frame 30 may firmly fix the wafer fixer 10 and the measuring unit 20 relative to each other. Further, the support frame 30 may function to integrally connect the wafer fixer 10 and the measuring unit 20 with each other in order to simplify a structure of the apparatus 100.

The first fixing portion 34 of the support frame 30 may be connected to a stage 12. When the stage 12 is fixed by the first fixing portion 34, the bonded wafer pair 110 may be stably placed on the stage 12. A body 240b of a linear driver 24b in the driver 24 may be attached to the second fixing portion 36 of the support frame 30. In one embodiment, the body 240b of the linear driver 24b is not moved nor rotated while measuring the wafer bonding strength. The stage 12 and the linear driver 24b are described in more detail later.

The support frame 30 may include a material for fixing the wafer fixer 10 to the measuring unit 20. For example, the material may include a stainless steel, etc., but the present invention is not limited thereto.

The wafer fixer 10 may include the stage 12 configured to fix the bonded wafer pair 110 in position. The wafer fixer 10 may further include a fixing member 14 configured to fix a planar position of the bonded wafer pair 110.

In various embodiments, the bonded wafer pair 110 may be placed on the stage 12. Thus, the stage 12 may support a lower surface of the bonded wafer pair 110. In this example, the stage 12 may include a vacuum chuck configured to support and fix the bonded wafers 110 using vacuum, an electrostatic chuck (ESC) configured to fix in position and support the bonded wafer pair 110 using an electrostatic force.

The stage 12 may be positioned under the bonded wafer pair 110 to support all the lower surface of the bonded wafer pair 110. In order to measure the wafer bonding strength, a force applied to the blade 10 may be measured when the wafers of the bonded wafer pair 110 are separated along a bonding interface 116. The stage 12 may not greatly affect the separation of the bonded wafers 110 at the bonding interface 116 so that the stage 12 may support the bonded wafer pair 110. When the stage 12 supports the bonded wafer pair 110, the bonded wafer pair 110 may be stably supported. In contrast, in a crack opening method, a crack length may be measured at a point where a deboning wave may spread after the edge portion of the bond wafer may be separated to measure the wafer bonding strength.

In other embodiments, one side 110a of the bonded wafer pair 110 adjacent to the measuring unit 20 into which the blade 22 may be inserted and one edge portion 12a of the stage 12 may be positioned on a same line. Thus, the bonded wafer pair 110 may be stably supported. Further, any unnecessary influence of the stage 12 may be minimized in measuring the wafer bonding strength, but the present invention is not limited thereto.

Alternatively, the one side 110a of the bonded wafer pair 110 may be positioned inwardly rather than the one edge portion 12a of the stage 12. Further, the stage 12 may support a part of the bonded wafer pair 110.

The fixing member 14, configured to fix the planar position of the bonded wafer pair 110, may be arranged on the stage 12. For example, the fixing member 14 may be positioned adjacent to an edge portion of the bonded wafer pair 110 (as shown for example in FIG. 2) to prevent the bonded wafer pair 110 from being moved in a horizontal direction. The fixing member 14 may include a wall, a step, etc., having a height substantially equal to or higher than a thickness of the bonded wafer pair 110.

FIG. 1 shows a first fixing member 14b, a second fixing member 14c and a third fixing member 14d of the fixing member 14. The first fixing member 14b may be arranged at the depicted side 110b of the bonded wafer pair 110 opposite to the depicted a side 110a of the bonded wafer pair 110, which may be adjacent to the measuring unit 20 in a first direction, i.e., an X-direction. The second and third fixing members 14c and 14d may be arranged adjacent to both sides 110c and 110d of the bonded wafer pair 110 in a second direction intersected with the first direction, i.e., a Y-direction. The first fixing member 14b may prevent the bonded wafer pair 110 from being undesirably moved using a force in the first direction applied to the bonded wafer pair 110 by the measuring unit 20. The second and third fixing members 14c and 14d may prevent the bonded wafers 110 from being shaken or otherwise moved in a direction intersected with the first direction, for example, left and right directions relative to the first direction.

The fixing member 14 may not be positioned at side 110a of the bonded wafer pair 110 adjacent to the measuring unit 20 in order to prevent the measurement of the wafer bonding strength by the measuring unit 20 from being interrupted.

The first fixing member 14b may have a linear shape extended in the second direction. The second and third fixing member 14c and 14d may have a linear shape extended in the first direction. When the bonded wafer pair 110 is placed and fixed in position, the bonded wafer pair 110 may be stably fixed with a minimum interference, but the present invention is not limited thereto.

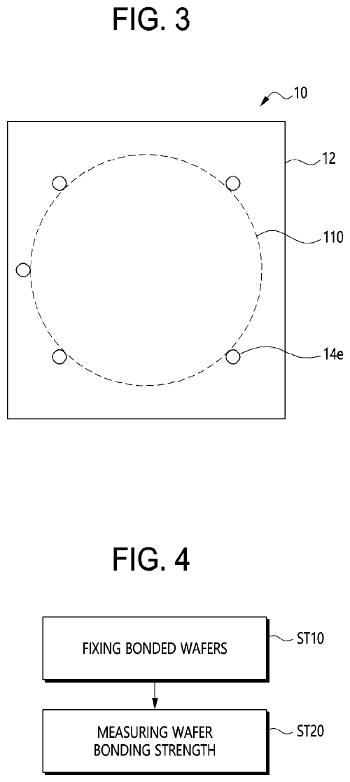

Alternatively, as shown in FIG. 3, a fixing member 14e may have an island shape. A plurality of the fixing members 14e may be positioned against sides of the bonded wafer pair 110 along the edge portion of the bonded wafer pair 110 along a circumferential direction with for example a uniform gap between the fixing members 14e. The fixing members 14e may not be arranged at the side 110a of the bonded wafer pair 110 adjacent to the measuring unit 20. Further, the fixing members 14e may not have the wall, the step, etc. noted above, but may each form a clamp. For example, the fixing members 14e may have a clamp shape configured to fix both side surfaces of the edge portion of the bonded wafer pair 110 in inserting the bonded wafers 110 into each clamp.

In various embodiments, the stage 12 may be configured to support the lower surface of the bonded wafer pair 110, but the present invention is not limited thereto. For example, the stage 12 may include a vice configured to fix the boned wafer pair 110.

In other embodiments, the bonded wafer pair 110 fixed by the wafer fixer 10 in position on stage 12 may be a structure including a first wafer 112 and a second wafer 114 bonded to each other. A structure, a material, a thickness, etc., of the first wafer 112 and the second wafer 114 may be substantially equal to or different from each other. For example, the bonded wafer pair 110 may include a memory device, but the present invention is not limited thereto.

The first wafer 112 and the second wafer 114 may have planes extending in the first direction and the second direction. The first wafer 112 and the second wafer 114 may have thicknesses in a third direction intersected with the first and second directions, i.e., a Z-direction. A contact plane between the first wafer 112 and the second wafer, i.e., an XY plane, may be the bonding interface 116.

In one embodiment, the measuring unit 20 includes the blade 22, the driver 24 and the sensor 26. The blade 22 may apply a force to the bonding interface 116 from the side 110a of the bonded wafers 110 to separate the bonded wafers 110. The driver 24 may provide the blade 22 with a driving force. The sensor 26 may measure the force applied to the blade 22. The separation of the wafers 112 and 114 of the bonded wafer pair 110 may form an opened state of the bonded wafer pair 110 by parting the first wafer 112 from the second wafer 114 to form a gap between the first wafer 112 and the second wafer 114.

The blade 22 may be positioned adjacent to the one side 110a of the bonded wafer pair 110. The blade 22 may apply the force to the bonding interface 116. The blade 22 may have a structure and a shape configured to be inserted into a space between the first wafer 112 and the second wafer 114. For example, the blade 22 may have a plane substantially parallel to the planes of the first and second wafers 112 and 114. The blade 22 may have a relatively thin thickness compared to wafers 112 and 114. The blade 22 may have a quadrangular plane shape. The blade 22 may have a sharp end having a gradually decreased thickness toward the bonded wafer pair 110 adjacent to side 110a of the bonded wafer pair 110. When blade 22 applies a force higher than a bonding strength to the bonding interface 116, wafers 112 and 114 of the bonded wafer pair 110 are separated so that the blade 22 is inserted into the space between the first wafer 112 and the second wafer 114.

The driver 24 may provide the blade 22 with a horizontal force in the first direction. That is, the driver 24 may provide the blade 22 with the force to forwardly move the blade 22 adjacent to the bonded wafer pair 110 and into the bonding interface 116 in measuring the wafer bonding strength. After measuring the wafer bonding strength, the driver 24 may provide the blade 22 with a force to backwardly move the blade from the bonded wafer 110. The forward direction toward the bonded wafer pair 110 may be along a direction D1 (shown in FIG. 1) and the backward direction from the bonded wafers 110 may be along a reverse direction D2 (shown in FIG. 1).

Particularly, when measuring the wafer bonding strength, the driver 24 may provide the blade 22 with a force in the direction D1 in a measurement section MS. The measurement section MS may extend from a contact point CP of the blade 22 with side 110a of the bonded wafers 110 to a part point PP of the blade 22 at a distance from the side 110a of the bonded wafers 110.

In measuring the wafer bonding strength, the driver 24 may provide the blade 22 with a force in direction D1 in a transfer section TS before reaching the measurement section MS. The transfer section TS may extend from a separation point SP of the blade 22 away from the bonded wafers 110 to the contact point CP. Further, the driver 24 may provide the blade 22 with a force in direction D1 in a part section PS after the measurement section MS. The part section PS may be a section after a part point PP at which the blade 22 contacts side 110a of the bonded wafer pair 110 and moves into the bonding interface 116.

In other embodiments, in measuring the wafer bonding strength, the driver 24 may provide the blade 22 with the same force while in the measurement section MS. Because the same force may be applied to the blade 22, the wafer bonding strength may be stably measured without an error. The same force may be a force including an unintended difference within a range such as an error, a clearance, etc. The driver 24 may provide the blade 22 with a force, which may be substantially the same as the force in the measurement section MS, in the transfer section TS although the blade itself may experience no strain in the transfer section TS where contact of blade 22 to the bonded wafer pair is not expected. Thus, the wafer bonding strength may be stably measured. In order to stably measure the force applied to the blade 22, the driver 24 may continuously provide the force, which may be substantially the same as the force in the measurement section MS, in the part section PS for a predetermined time. After the predetermined time, the driver 24 may not provide the blade 22 with any force.

In other embodiments, the driver 24 may include a rotary driver 24a and a linear driver 24b. The linear driver 24b may provide the blade 22 with a force to move the blade in the direction D1 or in reverse direction D2. The linear driver 24b may include a body 240b and a moving member 242b. The body 240b may generate a driving force for linearly moving the blade 22. The moving member 242b may transfer the driving force to the blade 22. The moving member 242b may protrude toward a front of body 240b. The moving member 242b may move in the direction D1 or in reverse direction D2. The linear driver 24b may directly generate the linearly driving force. Alternatively, the linear driver 24b may convert a rotary motion into a linear motion to generate the linearly driving force.

In one example, the driver 24 may include a rotary driver 24a and the linear driver 24b positioned at a front of the rotary driver 24a, i.e., in a direction adjacent to the bonded wafer pair 110 so that a cost of the driver 24 may be decreased.

The rotary driver 24a may include a direct current servo motor. The servo motor may control a rotation speed and a RPM through a control signal different from a general motor. Thus, the servo motor may effectively control the driving force provided to the blade 22 in assessing the wafer bonding strength. Further, the servo motor may have a rapid signal response speed. The body 240b of the linear driver 24b may include various members configured to convert the rotary motion into linear motion. Various structures and types may be applied to the body 240b. In one example, the linear driver 24b may include a rotary to linear motion converter, but the present invention is not limited thereto.

Alternatively, the driver 24 may include only a linear driver 24b without the rotary driver 24a. In this case, a structure may be simplified to provide a stable linearly driving force. The body 240b may include various members configured to generate the linearly driving force. In one example, the linear driver 24b may include a linear motor. The moving member 242b may protrude toward the front of the body 240b. The moving member 242b may be moved in direction D1 or in the reverse direction D2.

The sensor 26 for measuring the force applied to the blade 22, (i.e., the blade force) may be arranged between the blade 22 and the driver 24, particularly, between the blade 22 and the moving member 242b. In one example, the sensor 26 may be positioned between a rear end of the blade 22 and a front end of the moving member 242b in the linear driver 24b. The moving member 242b may be moved in the direction D1 to provide the blade 22 with the force. The moving member 242b may make contact with the side 110a of the bonded wafer pair 110. Particularly, the sensor 26 may make contact with a rear end of the blade 22 and a front end of the moving member 242b in the linear driver 24b. The sensor 26 between the blade 22 and the moving member 242b may stably and accurately measure the wafer bonding strength without using any member.

The sensor 26 between the blade 22 and the driver 24 may measure a compressive force. In one example, the sensor 26 may include a compressive load cell.

For example, the compressive load cell may include a spring with a strain gauge. The strain gauge may include steel, an aluminum, etc. The spring may have resilience. Thus, when a pressure is applied to the spring, the spring may be deformed and returned to an original position. The strain gauge may detect the change of the spring. In one example, the strain gauge may include an electrical conductor attached to a film in a zigzag pattern. As a length of the film may be changed, a length of the electrical conductor may also be changed so that a resistance of the electrical conductor may be changed to determine a strain.

The sensor 26 may continuously measure the force applied to the blade 22 in the measurement section MS. That is, the driver 24 may provide the blade 22 with a constant force in the measurement section MS. Because the blade 22 may make contact with the side 110a of the bonded wafers 110 in the measurement section MS, when the driver 24 provides the blade 22 with the force, a compressive force is generated between the blade 22 and the driver 24, particularly, between the blade 22 and the moving member 242b. The sensor 26 can measure the compressive force to obtain the force applied to the blade 22.

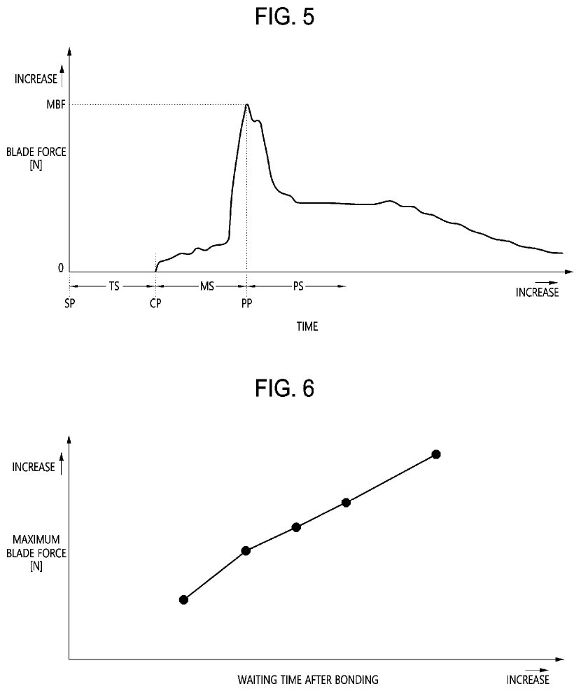

When the force applied to the blade 22 is substantially the same as the wafer bonding strength, by gradually increasing the force, side 110a of the bonded wafer pair 110 may be parted so that the first wafer 112 and the second wafer 114 become separated from each other. That is, the force applied to the blade 22 at the part point PP may be a maximum force (as shown in FIG. 5). The maximum force may be substantially the same as the wafer bonding strength. Thus, the maximum force among the forces applied to the blade 22 may be determined as the wafer bonding strength.

In one embodiment, the compressive force measured by the sensor 26 may be stored in an analyzer 26a. The analyzer 26a may analyze the compressive force. That is, the forces continuously measured by the sensor 26 may be recorded in the analyzer 26a connected to the sensor 26. The analyzer 26a may determine the maximum force among the forces applied to the blade 22 as the wafer bonding strength.

In further embodiments, the sensor 26 and the analyzer 26a connected to the sensor 26 may be separated elements, but the present invention is not limited thereto. Alternatively, when the sensor 26 includes a digital load cell, the sensor 26 and the analyzer 26a can perform recording, processing and displaying the measurement results. An additional power source different from a power source of the driver 24 may be connected with the sensor 26, but the present invention is not limited thereto.

The sensor 26 may be fixed to the blade 22 and the moving member 242b by various fixing members. For example, the blade 22 may be fixed to the sensor 26 using a screw. When the blade 22 may be repeatedly used, it may be required to periodically change the blade 22. In this case, the blade 22 may be readily changed by the screw. The sensor 26 may be fixed to the moving member 242b by a screw, an adhesive, a fixing member, etc. The fixing structure between the sensor 26 and the blade 22 and/or the moving member 242b may be variously changed.

According to the disclosed embodiments above, the wafer bonding strength may be directly measured, and thereby the accuracy and the precision of the wafer bonding strength are improved.

Hereinafter, an operation method of the measurement apparatus 100 and a measurement method of the wafer bonding strength may be illustrated with reference to FIGS. 1, 2, 4 and 5. In the description below, the blade force may refer to the force applied to the blade 22.

FIG. 4 is a flow chart illustrating a method of operating a measurement apparatus of wafer bonding strength in accordance with various embodiments of the present invention, and FIG. 5 is a graph showing blade forces in accordance with times during which an apparatus for measuring wafer bonding strength is measuring the force applied to blade 22.

Referring to FIGS. 1, 2, 4 and 5, a method of operating the measurement apparatus may include an operation ST10 for fixing the bonded wafers (e.g., the bonded wafer pair 110) and an operation ST20 for measuring wafer bonding strength. In various embodiments, in operation ST20, the wafer bonding strength may be determined by measuring the blade force. Thus, the operation ST20 may correspond to an operation for measuring the blade force.

In operation ST10, the bonded wafer pair 110 may be fixed in position to the wafer fixer 10. That is, the bonded wafer pair 110 may be placed on the stage 12. The fixed planar position of the bonded wafer pair 110 may be maintained by fixing member(s) 14. The blade 22 of the driver 20 may be positioned at the spaced point SP spaced apart from side 110a of the bonded wafer pair 110.

In operation ST20, the driver 24 may be driven to contact the blade 22 with the bonding interface 116 of the bonded wafer pair 110 and to apply force the blade 22 while inserting the tip of the blade 22 into the bonding interface 116. The force applied to the blade 22 may be measured to determine or measure the wafer bonding strength.

The operation ST20 may include the transfer section TS, the measurement section MS and the part section PS. The operation ST20 may transfer the blade 22 through the transfer section TS, the measurement section MS and the part section PS. As mentioned above, in operation ST20, the driver 24 may provide the blade 22 with the same force in direction D1 while in the measurement section MS. Further, the driver 24 may provide the blade 22 with the same force in the transfer section TS and/or a part of the part section PS adjacent to the part point PP so that the force applied to the blade 22 may be stably measured. The force applied to the blade 22 by the driver 24 may be substantially equal to or more than the wafer bonding strength.

When the driver 24 provides the blade 22 with the force along the direction D1 in the transfer section TS, the blade 22 in the spaced point SP may be moved to the contact point CP. The blade 22 may be moved by the force applied to the moving member 242b in the transfer section MS. Because a structure for blocking the blade 22 might not exist in the transfer section TS, the blade 22 experiences no strain. Thus, a force measured by the sensor 26 in the transfer section TS may be about 0.

The driver 24 may continuously push the blade 22 at the contact point CP along direction D1 in the measurement section MS. Because the blade 22 is blocked by the bonded wafer pair 110 so that the blade 22 might not move in direction D1 any more, the blade 22 (between the driver 24 and the bonded wafers 110) may continuously experience an increased force and strain until the blade 22 reaches the part point PP. The force applied to the blade 22 may gradually increase in the measurement section MS. Particularly, when the blade 22 starts to separate the first wafer 112 and the second wafer 114 from each other at the bonding interface 116 of the bonded wafer pair 110, a maximum resistance is generated. After the first wafer 112 and the second wafer 114 are parted from each other, the resistance decreases so that the force experienced by the blade 22 also decreases. Thus, the force experienced by the blade 22 at the part point PP will be the maximum force. The force measured by the sensor 26 in the measurement section MS may accordingly be gradually increase to a maximum value.

Because the first wafer 112 and the second wafer 114 may be parted from each other in the part section PS, the force applied to and experienced by the blade 22 will decrease after the part point PP. Thus, the force measured by the sensor 26 in the part section PS will also decrease.

The force continuously measured by the sensor 26, (i.e., the blade force) may have a shape as in FIG. 5. That is, the blade force in the transfer section TS may be about 0. The blade force may be increased from the contact point CP to the part point PP to have the maximum value at the part point PP. The blade force may be greatly decreased after the part point PP.

The force applied to the blade 22 may become equal to or more than the wafer bonding strength at the part point PP to part the bonded wafers 110. Thus, the maximum value of the blade force measured at the part point PP, i.e., a maximum blade force MBF, corresponds to the wafer bonding strength.

The blade force continuously measured by the sensor 26 may be recorded in the analyzer 26a connected to the sensor 26. The analyzer 26a may determine the maximum blade force MBF as the wafer bonding strength.

The wafer bonding strength may be represented by N value as a unit of the force. The N value may be determined as a relative value of the wafer bonding strength so that the N value may be used for comparing the wafer bonding strength with each other. Alternatively, the N value may be converted into J/m² corresponding to a unit of a wafer bonding strength in the crack opening method to be used for determining the wafer bonding strength.

According to various embodiments, the force may be applied to the blade 22 making contact with the bonding interface 116 of the bonded wafers 110. The force applied to the blade 22 may be measured to determine the wafer bonding strength. Particularly, the wafer bonding strength may be determined as the maximum blade force MBF applied to or experienced by the blade 22 when the bonding interface 116 of the bonded wafers 110 is parted.

That is, the maximum blade force MBF at the part point PP may be directly measured to determine the wafer bonding strength. Thus, it might not be required to consider a crack depth, a crack shape, etc., in the part section PS as in the prior crack opening method(s). Further, because the maximum blade force MBF at the part point PP may be measured, the driver 24 may be stopped after the part point PP so that any force may no longer be applied to the blade 22.

Therefore, a crack opening force, which may directly relate to the wafer bonding strength, i.e., the maximum blade force MBF may be directly measured to determine the wafer bonding strength. When the methods of the herein disclosed embodiments are compared with the prior crack opening method(s) for indirectly inferring the surface energy by measuring the crack length, the accuracy of the wafer bonding strength of the present invention may be improved. Particularly, the methods of the herein disclosed embodiments might not require a waiting time for the spread of the crack so that the methods of the herein disclosed embodiments might not be affected by the peripheral environments, the measurement type, etc. That is, the factors affecting the measurement of the wafer bonding strength may be only two, that of a) the force applied to the blade 22, i.e., an insertion force, and b) the specification of the sensor 26. Thus, the accuracy and the precision of the wafer bonding strength may be remarkably improved.

Feasibility of the herein disclosed methods for measuring the wafer bonding strength using the inventive measurement apparatus is shown by following experiments. However, the experiments are exemplarily, and the present invention is not limited thereto.

FIG. 6 is a graph showing a relation between a waiting time after wafer bonding and a maximum blade force measured using an apparatus of the herein disclosed embodiments.

The maximum blade force with respect to the bonded wafers, which may have different waiting times after bonding, may be measured using the inventive measurement apparatus disclosed herein.

Referring to FIG. 6, when the waiting time after bonding is increased, it can be noted that the maximum blade force measured by the inventive measurement apparatus may be increased. Further, it can be noted that the maximum blade force measured by the inventive measurement apparatus may be linearly increased in proportion to increasing of the waiting time, i.e., the wafer bonding strength. Thus, it can be noted that the wafer bonding strength may be effectively determined using the inventive measurement apparatus.

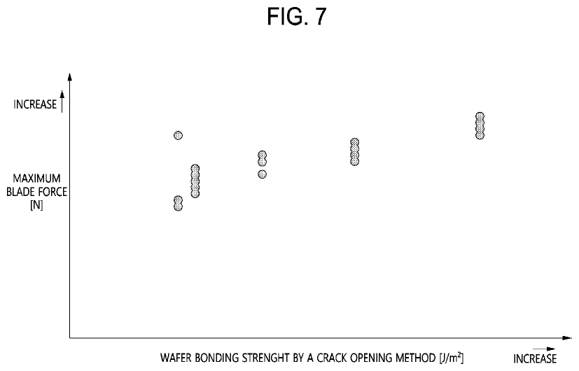

FIG. 7 is a graph showing a maximum blade force measured using the inventive apparatus of example embodiments versus wafer bonding strength by a prior crack opening method.

Referring to FIG. 7, it can be noted that the maximum blade force measured by the inventive measurement apparatus may be increased in proportion to increasing of the wafer bonding strength by the prior crack opening method. Thus, it can be noted that the maximum blade force measured by the inventive measurement apparatus may be linearly increased in proportion to increasing of the wafer bonding strength by the prior crack opening method. Thus, it can be noted that the wafer bonding strength may be effectively determined using the inventive measurement apparatus of example.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications in view of the present disclosure are readily apparent and are intended to fall within the scope of the present disclosure.

What is claimed is:

1. An apparatus for measuring wafer bonding strength, the apparatus comprising:
a wafer fixer configured to fix bonded wafers in position; and
a measuring unit configured to measure the wafer bonding strength of the bonded wafers,
wherein the measuring unit comprises:
a blade configured to apply a force to a bonding interface between the bonded wafers from a contact side of the bonded wafers to part the bonded wafers;
a driver configured to provide the blade with a driving force; and
a sensor configured to measure the forces applied to the blade.

2. The apparatus of claim 1, wherein the sensor is positioned between the blade and the driver to measure a compressive force.

3. The apparatus of claim 2, wherein the sensor comprises a compressive load cell.

4. The apparatus of claim 2, wherein the sensor continuously measures the forces applied to the blade in a measurement section extending from a contact of the blade with the contact side of the bonded wafers to a parting point for the bonded wafers.

5. The apparatus of claim 4, wherein a maximum value among the forces applied to the blade is determined as the wafer bonding strength.

6. The apparatus of claim 4, wherein the measuring unit further comprises an analyzer configured to determine the wafer bonding strength from the forces applied to the blade measured by the sensor.

7. The apparatus of claim 2, wherein the driver provides the blade with a force along a direction in a measurement section from a contact of the blade with the contact side of the bonded wafers to a parting point for the bonded wafers.

8. The apparatus of claim 7, wherein the driver provides the blade with a same force in the measurement section.

9. The apparatus of claim 1, wherein the driver comprises a linear driver, the linear driver comprises a body configured to generate the driving force for a linear motion and a moving member configured to transfer the driving force to the blade, and the sensor is positioned between the moving member and the blade.

10. The apparatus of claim 1, further comprising a support frame configured to fix together and support the wafer fixer and the measuring unit.

11. The apparatus of claim 1, wherein
the wafer fixer comprises a stage configured to receive the bonded wafers, and
the stage is configured to support the bonded wafers.

12. The apparatus of claim 11, wherein the wafer fixer further comprises a fixing member configured to fix a planar position of the bonded wafers on the stage.

13. A method of measuring wafer bonding strength, the method comprising:
applying forces to a blade making contact with a bonding interface between bonded wafers; and
measuring the forces applied to the blade to determine the wafer bonding strength.

14. The method of claim 13, wherein a maximum value among the forces applied to the blade when the bonding interface is parted is determined as the wafer bonding strength.

15. A method of driving a measurement apparatus of wafer bonding strength, the method comprising:
fixing bonded wafers to a wafer stage; and
driving a driver, which provides a blade with a driving force, to apply forces to the blade making contact with a bonding interface between the bonded wafers; and
measuring the forces applied to the blade to determine the wafer bonding strength.

16. The method of claim 15, wherein a maximum value among the forces applied to the blade when the bonding interface is parted is determined as the wafer bonding strength.

17. The method of claim 15, wherein measuring the forces comprises measuring a compressive force by a sensor between the driver and the blade.

18. The method of claim 15, wherein measuring the forces comprises providing a same force to the blade in a measurement section from a contact of the blade with a contact side of the bonded wafers to a parting point for the bonded wafers.

19. The method of claim 15, wherein measuring the forces comprises:
recording the forces applied to the blade in an analyzer; and
determining by the analyzer the wafer bonding strength from the forces applied to the blade.
